(19) United States
(12) Patent Application Publication
(10) Pub. No.: US 2013/0279089 A1
(43) Pub. Date: Oct. 24, 2013

(54) COVER, ELECTRONIC DEVICE AND MANUFACTURING METHOD FOR COVER

(71) Applicant: HTC Corporation, (US)

(72) Inventors: Shih-Po Chien, Taoyuan County (TW); Hsien-Wei Juan, Taoyuan County (TW); I-Cheng Chuang, Taoyuan County (TW); Yi-Ting Liu, Taoyuan County (TW); Chih-Kai Hu, Taoyuan County (TW); Chun-Lung Huang, Taoyuan County (TW); Pi-Lin Lo, Taoyuan County (TW); Yi-Fan Hsueh, Taoyuan County (TW)

(73) Assignee: HTC Corporation, Taoyuan County (TW)

(21) Appl. No.: 13/650,126

(22) Filed: Oct. 11, 2012

Related U.S. Application Data
(60) Provisional application No. 61/583,561, filed on Jan. 5, 2012.

(51) Int. Cl. H05K 13/00; H05K 7/00

(52) U.S. Cl. CPC H05K 13/00; H05K 7/005
USPC 361/679.01; 427/207.1; 428/354

(57) ABSTRACT

A cover, an electronic device and a method for manufacturing the cover are provided. The electronic device includes a body and a cover. The cover is disposed on the body, and includes a substrate, an adhesive layer and a color layer. The substrate has a thinning region. The color layer is disposed in the thinning region and is located between the substrate and the adhesive layer.

### CROSS-REFERENCE TO RELATED APPLICATION

This application claims the priority benefits of U.S. provisional application Ser. No. 61/583,561, filed on Jan. 5, 2012. The entirety of the above-mentioned patent application is hereby incorporated by reference herein and made a part of this specification.

### BACKGROUND

1. Technical Field

The application relates to a cover. Particularly, the application relates to a structure and a method for assembling a cover to an electronic device.

2. Related Art

Along with a quick development of electronic devices, various thin type display techniques are applied on display modules of the electronic devices, for example, liquid crystal display (LCD) modules and organic light emitting displays (OLEDs), etc.

FIG. 1 is a schematic diagram of a conventional electronic device. FIG. 2 is a cross-sectional view of a region A of the electronic device of FIG. 1. Referring to FIG. 1 and FIG. 2, the electronic device 100 includes a body 110, a display module 120, a touch panel 130 and a cover 140. The cover 140 is disposed on the body 110. The cover 140 includes a substrate 142, an adhesive layer 144 and a color layer 146. The touch panel 130 is disposed between the display module 120 and the adhesive layer 144, and is adhered to the substrate 142 through the adhesive layer. The color layer 146 is disposed on a flat surface of the substrate 142, and a height difference H exists between the surface of the color layer 146 and the surface of the substrate 142. Due to the height difference H, when the adhesive layer 144 covers the surfaces of the color layer 146 and the substrate 142, it is easy to form a gap G at a junction of the three parts, and people can see bubbles at the gap G from an appearance of the electronic device 100.

FIG. 3 is a cross-sectional view of a region B of the electronic device of FIG. 1. Referring to FIG. 3, the color layer 146 has an icon region 148, which is used to display a pattern of a function key. However, the ink coated on the icon region 148 has an uneven thickness and has a depression 148a. When the adhesive layer 144 covers the surfaces of the icon region 148 and the color layer 146, it is easy to form a gap at the depression 148a, which becomes visible bubbles in the appearance of the electronic device 100.

### SUMMARY

The application is directed to a cover, which resolves a problem of bubbles produced when an adhesive layer is configured.

The application is directed to an electronic device, in which a cover is free from a problem of bubble generation.

The application is directed to a method for manufacturing a cover, which resolves a problem of bubbles produced when an adhesive layer is configured.

The application provides a cover including a substrate, an adhesive layer and a color layer. The substrate has a thinning region. The color layer is disposed in the thinning region and is located between the substrate and the adhesive layer.

The application provides an electronic device including a body and a cover. The body includes a display module. The cover is disposed on the display module. The cover includes a substrate, an adhesive layer and a color layer. The substrate has a thinning region. The color layer is disposed in the thinning region and is located between the substrate and the adhesive layer.

The application further provides a method for manufacturing a cover, which includes following steps. A substrate is provided, a color layer is disposed in a thinning region of the substrate. Then, an adhesive layer is configured to cover the color layer and the substrate.

According to the above descriptions, by decreasing a height difference between the surface of the substrate and the surface of the color layer, generation of bubbles due to subsequent configuration of the adhesive layer can be effectively avoided.

In order to make the aforementioned and other features and advantages of the application comprehensible, several exemplary embodiments accompanied with figures are described in detail below.

### BRIEF DESCRIPTION OF THE DRAWINGS

The accompanying drawings are included to provide a further understanding of the application, and are incorporated in and constitute a part of this specification. The drawings illustrate embodiments of the application and, together with the description, serve to explain the principles of the application.

FIG. 1 is a schematic diagram of a conventional electronic device.

FIG. 2 is a cross-sectional view of a region A of the electronic device of FIG. 1.

FIG. 3 is a cross-sectional view of a region B of the electronic device of FIG. 1.

FIG. 4 is a schematic diagram of an electronic device according to an embodiment of the application.

FIG. 5A is a schematic diagram of a cover of FIG. 4 combined with a display module.

FIG. 5B is a schematic diagram of a substrate of FIG. 5A.

FIG. 6A is a schematic diagram of a cover according to another embodiment of the application.

FIG. 6B is a schematic diagram of a substrate of FIG. 6A.

FIG. 7A is a schematic diagram of a cover according to still another embodiment of the application.

FIG. 7B is a schematic diagram of a substrate of FIG. 7A.

FIG. 8 is a schematic diagram of a cover according to yet another embodiment of the application.

FIG. 9 is a text flowchart illustrating a method for manufacturing the cover of FIG. 5A.

FIGS. 10A-10F are schematic diagrams illustrating a process of manufacturing the cover of FIG. 5A.

FIGS. 11A-11E are schematic diagrams illustrating a process of manufacturing the cover of FIG. 6A.

FIGS. 12A-12F are schematic diagrams illustrating a process of manufacturing the cover of FIG. 8.

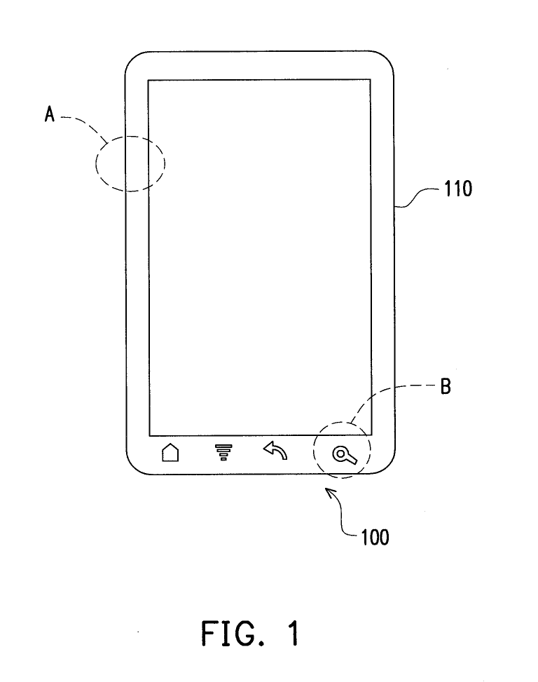

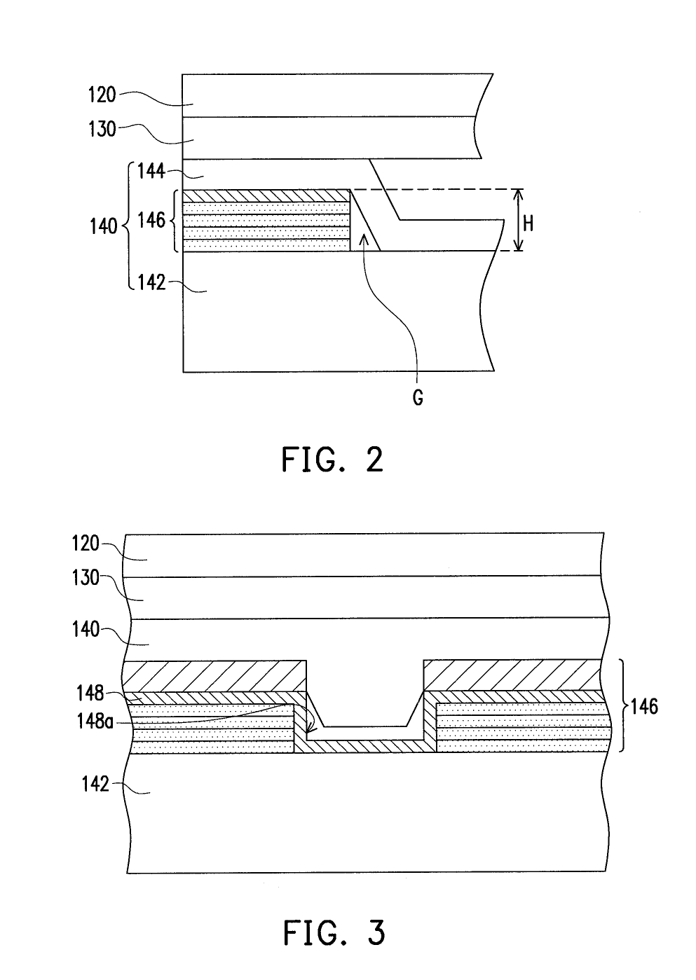

### DETAILED DESCRIPTION OF DISCLOSED EMBODIMENTS

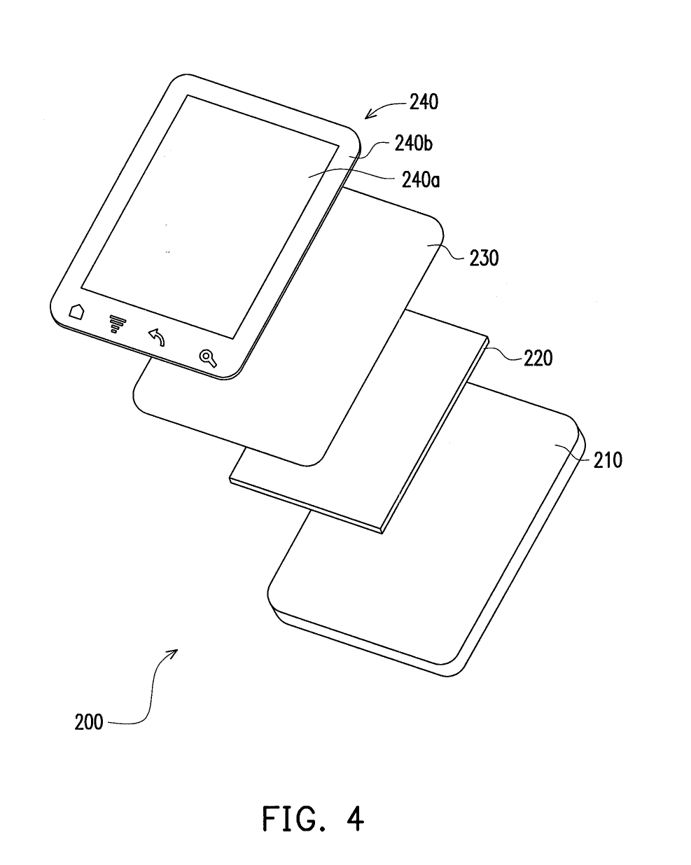

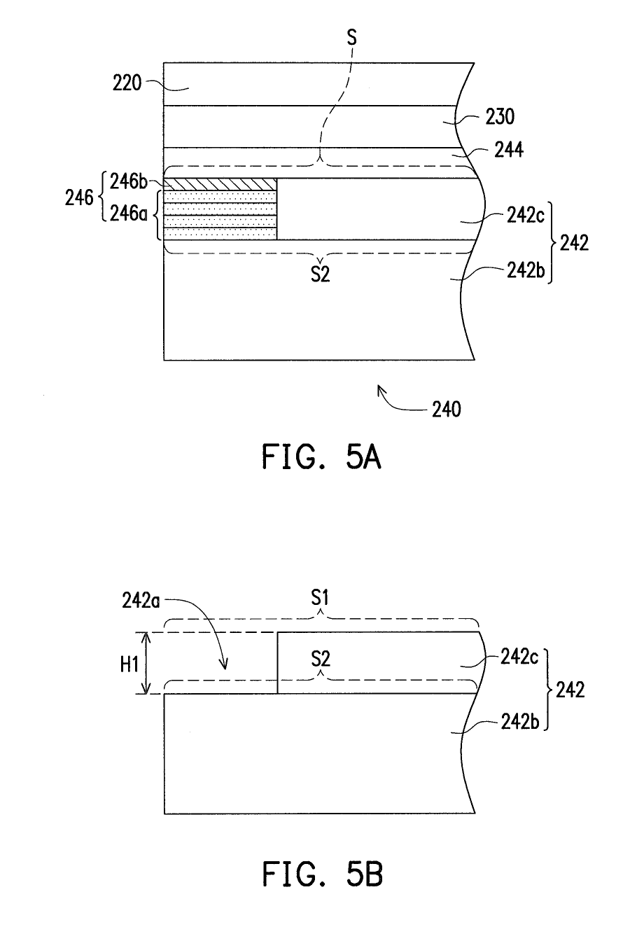

FIG. 4 is a schematic diagram of an electronic device according to an embodiment of the application. FIG. 5A is a schematic diagram of a cover of FIG. 4 combined with a display module. Referring to FIG. 4 and FIG. 5A, the electronic device 200 of the present embodiment includes a body 210, a touch panel 230 and a cover 240. The body 210 includes a display module 220. The cover 240 is disposed on the display module 220. The cover 240 includes a substrate 242, an adhesive layer 244 and a color layer 246, where the cover 240 includes a display zone 240a and a decoration zone 240b, a position of the display module 220 corresponds to a position of the display zone 240a, and the color layer 246 is disposed in the decoration zone 240b. The touch panel 230 is disposed between the display module 220 and the adhesive layer 244. In the present embodiment, the touch panel 230 is adhered to the substrate 242 through the adhesive layer 244. The touch panel 230 is, for example, a capacitive touch panel. In other embodiments, the touch panel 230 can also be a resistive touch panel or other types of touch panel.

In the present embodiment, in the present embodiment, the cover 240 that covers the touch panel 230 not only beautifies the appearance of the electronic device 200, but also protects the touch panel 230 from being damaged by an external force. For example, a material of the substrate 242 of the cover 240 is a transparent plastic or glass.

FIG. 5B is a schematic diagram of the substrate of FIG. 5A. Referring to FIG. 5A and FIG. 5B, the substrate 242 of the present embodiment has a thinning region 242a. In other words, a surface S1 of the substrate 242 is not a flat surface, and a height difference H1 exists between the thinning region 242a and the other part of the substrate 242. The color layer 246 is disposed in the thinning region 242a and is located between the substrate 242 and the adhesive layer 244. Under such configuration, the color layer 246 disposed in the thinning region 242a of the substrate 242 fills up the height difference H1, and the adhesive layer 244 may tightly fit the color layer 246 and the substrate 242 without forming a gap therebetween, so as to decrease a possibility of bubble existence.

In the application, by decreasing or eliminating a height difference at a junction of the color layer 246 and the substrate 242, it has a low possibility to form bubbles when the adhesive layer 244 is configured.

In the present embodiment, the substrate 242 of the cover 240 includes a bottom plate 242b and a filled layer 242c. The bottom plate 242b has a plane S2. The filled layer 242c is disposed on the plane S2, and a part of the plane S2 that is not configured with the filled layer 242c is the thinning region 242a. In the present embodiment, a surface of the filled layer 242c is aligned with a surface of the color layer 246, namely, the filled layer 242c and the color layer 246 commonly form the flat surface S. Moreover, a material of the filled layer 242c of the cover 240 is an optical grade UV glue, high penetration ink, optical clear adhesive/liquid optical clear adhesive/optical clear resin (OCA/LOCA/OCR) or silicon dioxide (SiO₂).

According to the above configuration, after the thinning region 242a of the substrate 242 is filled up by the color layer 246, the filled layer 242c and the color layer 246 can commonly form the flat surface S. Since the flat surface S does not have the height difference, the adhesive layer 244 can tightly fit the color layer 246 and the substrate 242 without forming a gap therebetween.

Moreover, the adhesive layer 244 disposed on the flat surface S of the filled layer 242c and the color layer 246 to adhere the touch panel 230 is made of a transparent adhesive material. In the present embodiment, the adhesive layer 244 is an OCA layer. On the other hand, the color layer 246 is, for example, an ink layer or a photoresist layer. In detail, the color layer 246 includes a white ink layer 246a and a black ink layer 246b. The black ink layer 246b is located between the white ink layer 246a and the adhesive layer 244 to block light. In other words, the part of the touch panel 230 and the display module 220 covered by the black ink layer 246b is invisible. The number of layers of the white ink layer 246a and the black ink layer 246b is not limited by the application. In other embodiments, the white ink layer 246a can be a single layer white ink or a multi-layer white ink. By using the multi-layer white ink, when the cover 240 is viewed from the substrate 242, the white ink layer 246a can provide a pure white appearance. An effect of the black ink layer 246b is to shield light probably leaked at peripheral of the display module 220 or avoid viewing an internal circuit when viewing through the substrate 242 of the cover 240. However, those skilled in the art can freely change the color and the structure of the color layer 246, so as to achieve a desired visual effect.

In the above embodiment, by configuring the filled layer 242c on the bottom plate 242b of the substrate 242, the filled layer 242c of the substrate 242 and the color layer 246 commonly form the flat surface S, so as to mitigate the problem of bubble generation when the adhesive layer 244 is configured. However, the method of using the substrate and the color layer to form the flat surface is not limited by the application, which is described below.

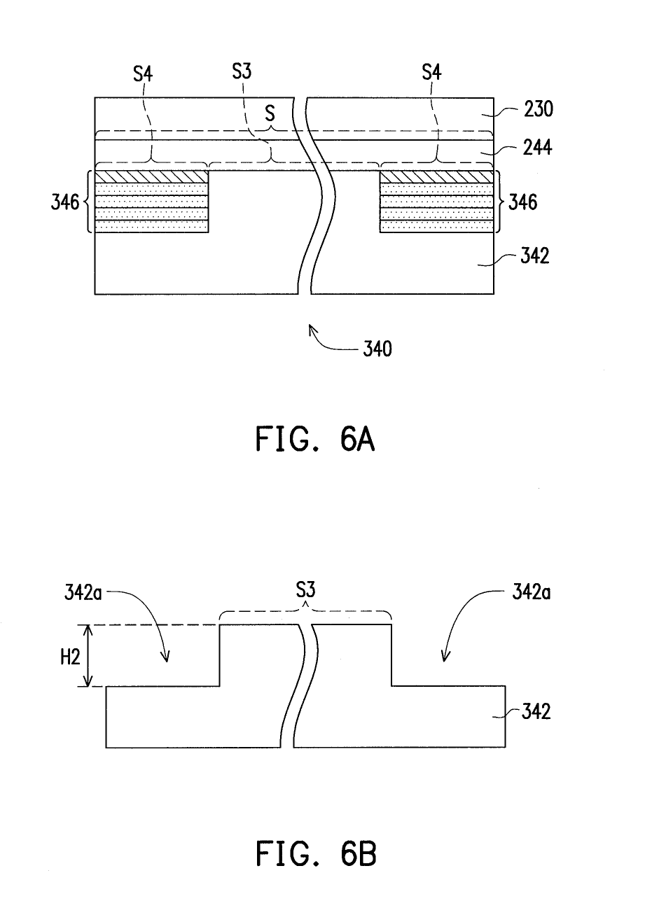

FIG. 6A is a schematic diagram of a cover according to another embodiment of the application. FIG. 6B is a schematic diagram of a substrate of FIG. 6A. Referring to FIG. 6A and FIG. 6B, the cover 340 of the present embodiment is similar to the cover 240 of the embodiment of FIG. 5A, where the same or like reference numerals refer to elements having the same or similar functions and shapes throughout, and detailed content and design can refer to related descriptions of FIG. 5A and FIG. 5B, which are not repeated. A difference therebetween is that a substrate 342 of the present embodiment is not configured with the filled layer of the above embodiment.

In detail, a thinning region 342a is directly formed on the substrate 342 made of a single material. In other words, a height difference H2 exists between a surface of the thinning region 342a of the substrate 342 and a surface S3 of the other part of the substrate 342. The substrate 342 is, for example, a glass substrate, a plastic substrate or other transparent substrate, and the thinning region 342a is, for example, formed through etching or other manner. A color layer 346 of the present embodiment is disposed in the thinning region 342a and located between the substrate 342 and the adhesive layer 244. A surface S4 of the color layer 346 is aligned with the surface S3 of a part of the substrate 342 that directly contacts the adhesive layer 244, so as to commonly form a flat surface S.

According to the above configuration, after the thinning region 342a of the substrate 342 is filled up by the color layer 346 to level the height difference H2, the adhesive layer 244 can tightly fit the surfaces of the color layer 346 and the substrate 342 without forming a gap therebetween.

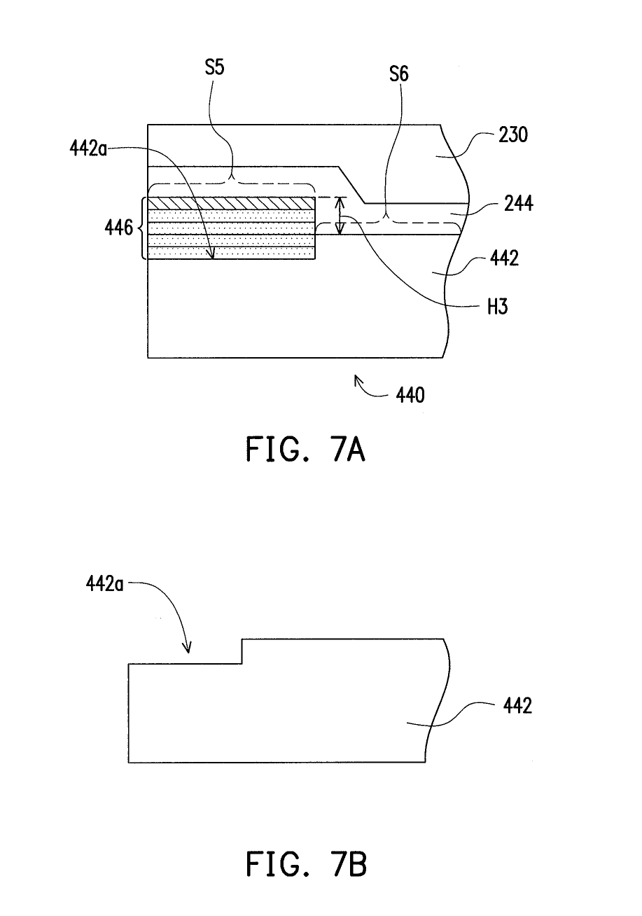

FIG. 7A is a schematic diagram of a cover according to still another embodiment of the application. FIG. 7B is a schematic diagram of a substrate of FIG. 7A. Referring to FIG. 7A and FIG. 7B, the cover 440 of the present embodiment is similar to the cover 340 of the embodiment of FIG. 6A, where the same or like reference numerals refer to elements having the same or similar functions and shapes throughout, and detailed content and design can refer to related descriptions of FIG. 6A and FIG. 6B, which are not repeated. A difference therebetween is that a surface S5 of a color layer 446 is higher than a surface S6 of a part of the substrate 442 that directly contacts the adhesive layer 244, and a height difference H3 is formed therebetween. According to such configuration, since the substrate 442 has a thinning region 442a, the height difference H3 is less than a thickness of the color layer 446, by which it has a low possibility to form bubbles when the adhesive layer 244 is configured.

The aforementioned embodiments all focus on methods of resolving the problem of bubbles formed at the edge of the display region of the electronic device 200, though the application can also resolve the problem of bubbles formed at an icon region of the electronic device 200, which is described below with reference of figures.

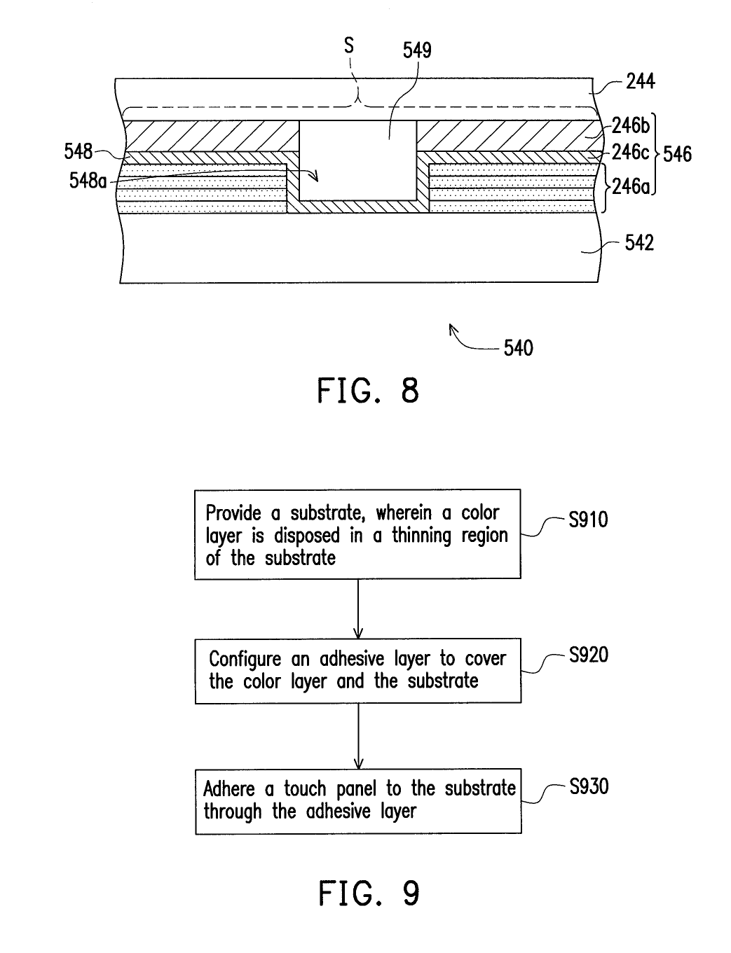

FIG. 8 is a schematic diagram of a cover according to yet another embodiment of the application. Referring to FIG. 8, description of the present embodiment focus on an icon region of the cover 540. A color layer 546 has an icon region 548 to display icons of function keys such as homepage, phone call, volume adjustment, etc.

In detail, the color layer 546 is disposed on the substrate 542, and the icon region 548 has a depression 548a. The cover 540 of the present embodiment further includes a filling material 549, and the filling material 549 fills in the depression 548a to substantially form a flat surface S with the color layer 546.

According to the above configuration, before the adhesive layer 244 is configured, the filling material 549 first fills in the depression 548a. After the filling material 549 fills the depression 548a, it commonly forms the flat surface S with the color layer 546. Therefore, the adhesive layer 244 may tightly fit the color layer 546 and the filling material 549 without forming a gap therebetween.

Moreover, a color of the color layer 546 at the icon region 548 is different to a color of the other part of the color layer 546. For example, the color layer 546 has the white ink layer 246a and the black ink layer 246b, and the color layer 546 has a gray ink layer 246c at the icon region 548 to highlight the icons of the icon region 548.

The cover 240 of FIG. 5A is taken as an example to describe a method for manufacturing the cover of the application.

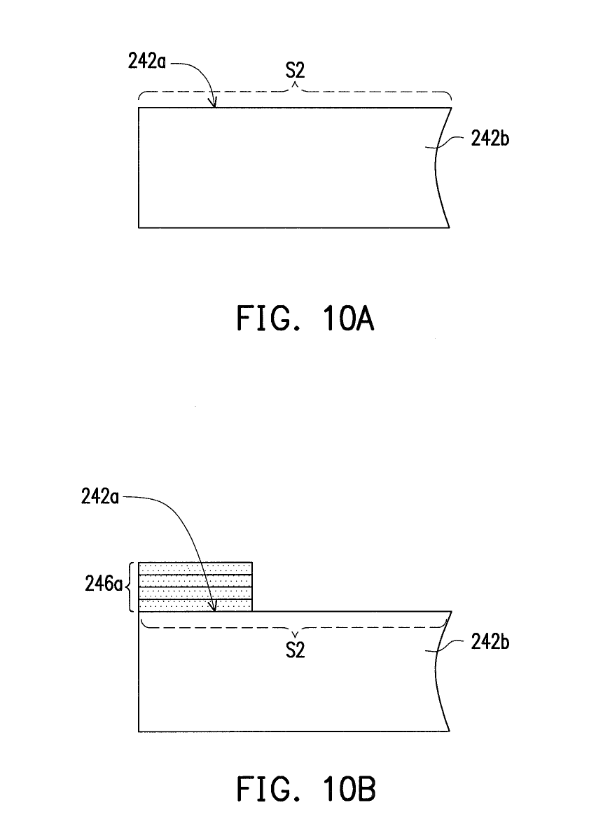

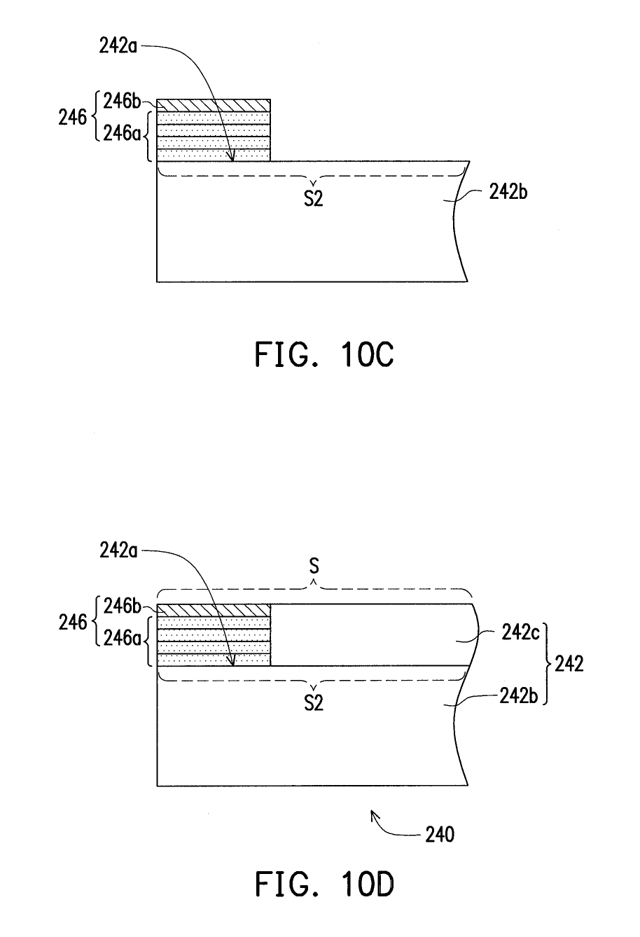

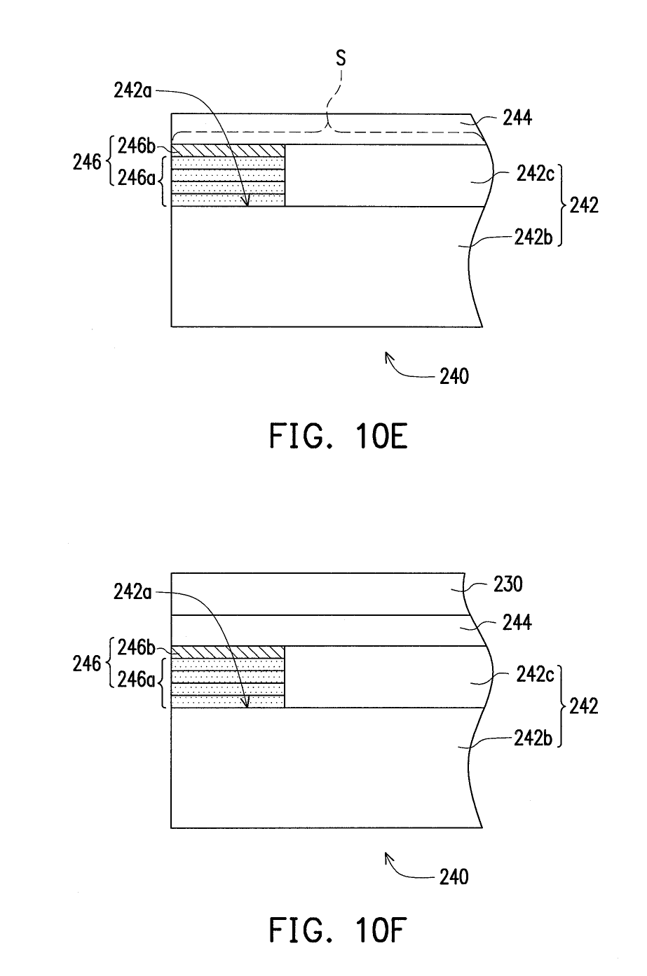

FIG. 9 is a text flowchart illustrating a method for manufacturing the cover of FIG. 5A. FIGS. 10A-10F are schematic diagrams illustrating a process of manufacturing the cover of FIG. 5A. Referring to FIG. 10D, the substrate 242 is provided, where the color layer 246 is disposed in the thinning region 242a of the substrate 242 (step S910).

In detail, the step S910 of providing the substrate 242 includes following steps. First, the bottom plate 242b shown in FIG. 10A is provided. The bottom plate 242b has a plane S2. Moreover, referring to FIG. 10C, the color layer 246 is disposed in the thinning region 242a of the plane S2.

Referring to FIG. 10D, the filled layer 242c is disposed on a part of the plane S2 that is not configured with the filled layer 246, and a surface of the filled layer 242c is aligned with a surface of the color layer 246, namely, the filled layer 242c and the color layer 246 commonly form the flat surface S.

Then, referring to FIG. 10E, the adhesive layer 244 is configured to cover the color layer 246 and the substrate 242 (step S920). In the present embodiment, according to the above manufacturing method, after the part of the bottom plate 242b that is not configured with the color layer 246 is filled by the filled layer 242c, the substrate 242 and the color layer 246 can commonly form the flat surface S. Therefore, the adhesive layer 244 may tightly fit the color layer 246 and the substrate 242 without forming a gap therebetween.

Referring to FIG. 10F, the method for manufacturing the cover 240 further includes a step of adhering the touch panel 230 to the substrate 242 through the adhesive layer 244 (step S930).

On the other hand, a method for manufacturing the color layer 246 of the step S910 includes following steps. First, referring to FIG. 10B, the white ink layer 246a is disposed in the thinning region 242a of the bottom plate 242b. Then, referring to FIG. 10C, the black ink layer 246b is disposed on the white ink layer 246a. The number of layers of the white ink layer 246a and the black ink layer 246b is not limited by the application. In other embodiments, the white ink layer 246a can be a single layer white ink or a multi-layer white ink.

In the aforementioned manufacturing method, by configuring the filled layer 242c on the bottom plate 242b of the substrate 242, the filled layer 242c of the substrate 242 and the color layer 246 commonly form the flat surface S to resolve the problem of bubbles generated when the adhesive layer 244 is configured. However, the method of using the substrate and the color layer to form the flat surface is not limited by the application, and the method for manufacturing the cover of the plate is described below with reference of the cover 340 of FIG. 6A.

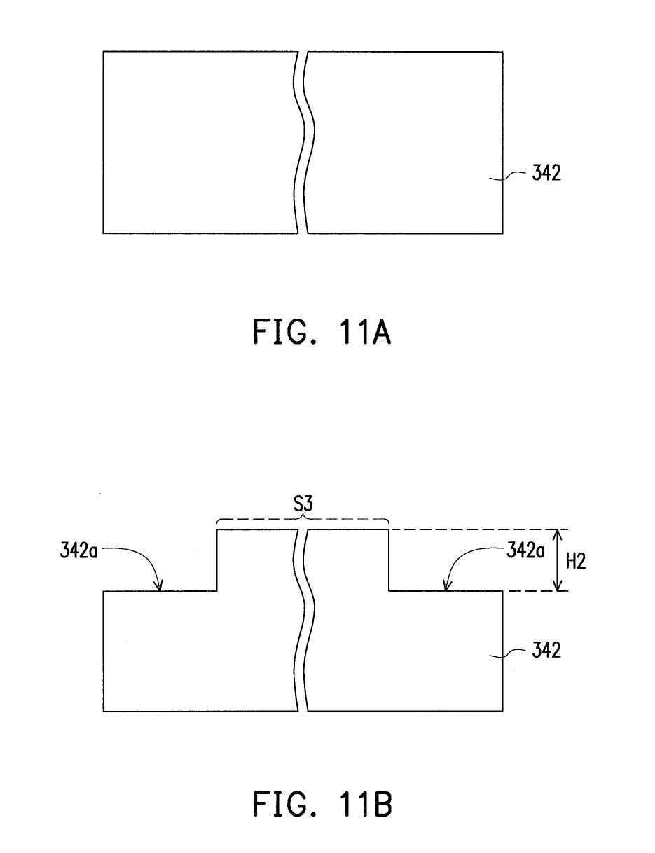

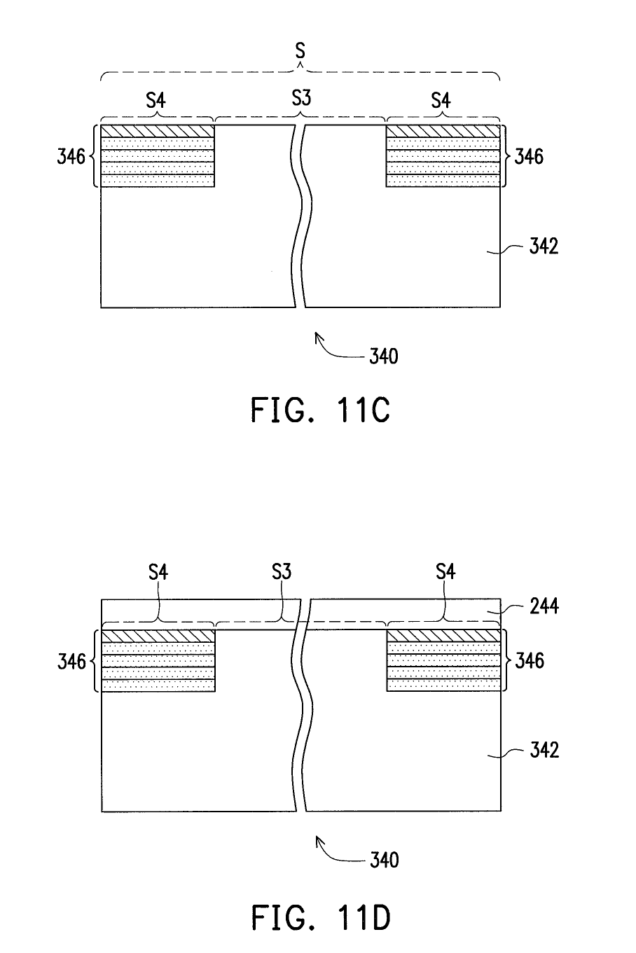

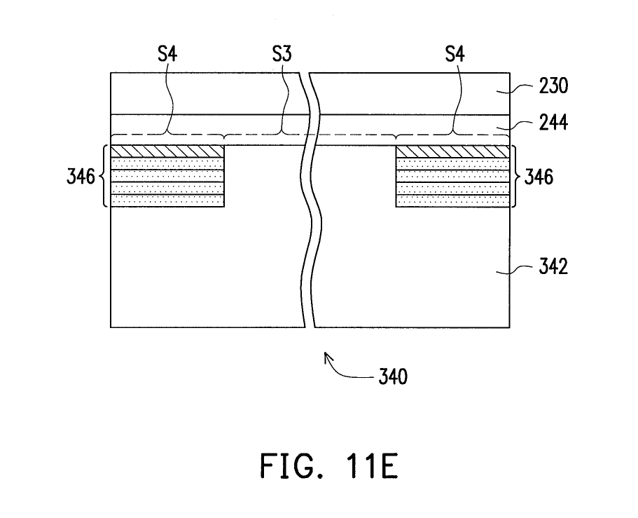

FIGS. 11A-11E are schematic diagrams illustrating a process of manufacturing the cover of FIG. 6A. The method for manufacturing the cover 340 of the present embodiment is similar to the method of the embodiment of FIGS. 10A-10F, where the same or like reference numerals refer to elements having the same or similar functions and shapes throughout, and detailed content and design can refer to related descriptions of FIGS. 10A-10F, which are not repeated. A difference therebetween is that the substrate 342 of the present embodiment is not configured with the filled layer of the above embodiment.

In detail, the method of providing the substrate 242 of the step S910 includes following steps. First, referring to FIG. 11B, the thinning region 342a is formed on the substrate 342 made of a single material. In other words, a height difference H2 exists between a surface of the thinning region 342a of the substrate 342 and a surface S3 of the other part of the substrate 342. In the present embodiment, the thinning region 342a is, for example, formed through etching or other manner.

Referring to FIG. 11C, the color layer 346 is disposed in the thinning region 342a of the substrate 342, and the surface S3 of a part of the substrate 342 other than the thinning region 342a is aligned with the surface S4 of the color layer 346, namely, the substrate 342 and the color layer 346 commonly form the flat surface S. Certainly, in other embodiments, the surface S5 of the color layer 446 can also protrude out from the surface S6 of a part of the substrate 442 that directly contacts the adhesive layer 244, as that shown in FIG. 7A.

Moreover, referring to FIG. 11D, the adhesive layer 244 is configured to cover the color layer 346 and the substrate 342 (step S920).

The aforementioned embodiments all take the cover of the display region of the electronic device as an example to describe the method for manufacturing the cover, though the application is also suitable for the icon region of the electronic device. The method for manufacturing the cover is described below with reference of the cover of the icon region of the electronic device of FIG. 8.

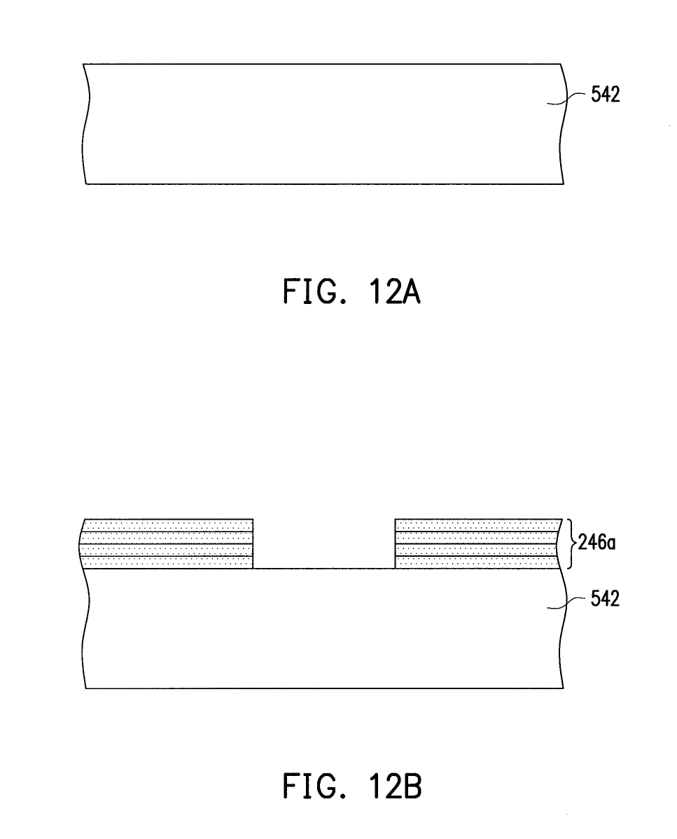

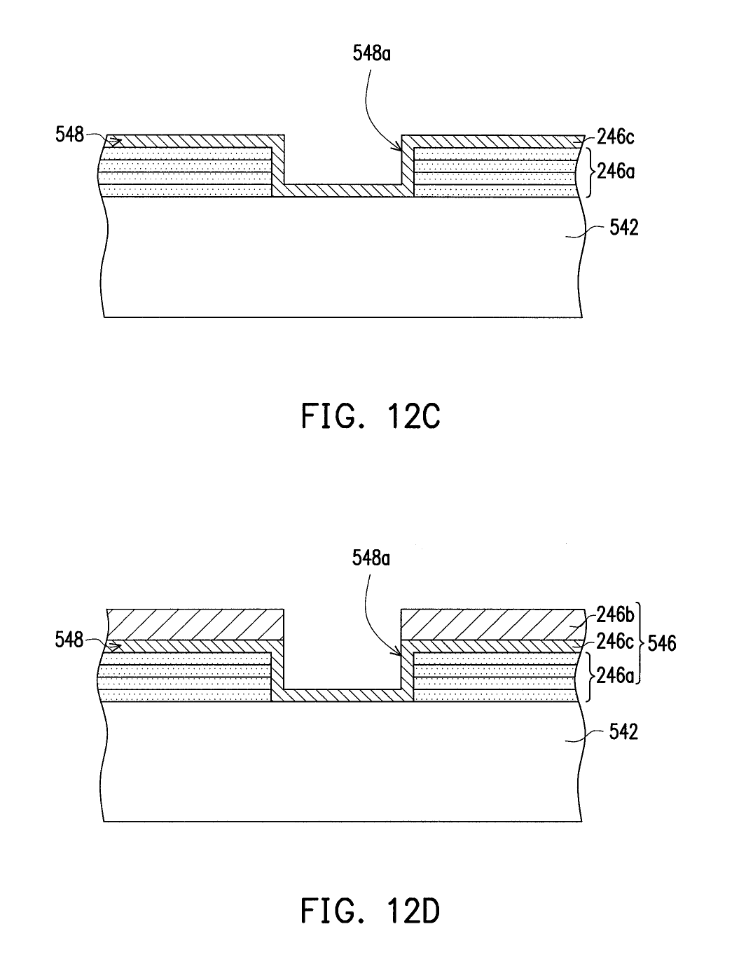

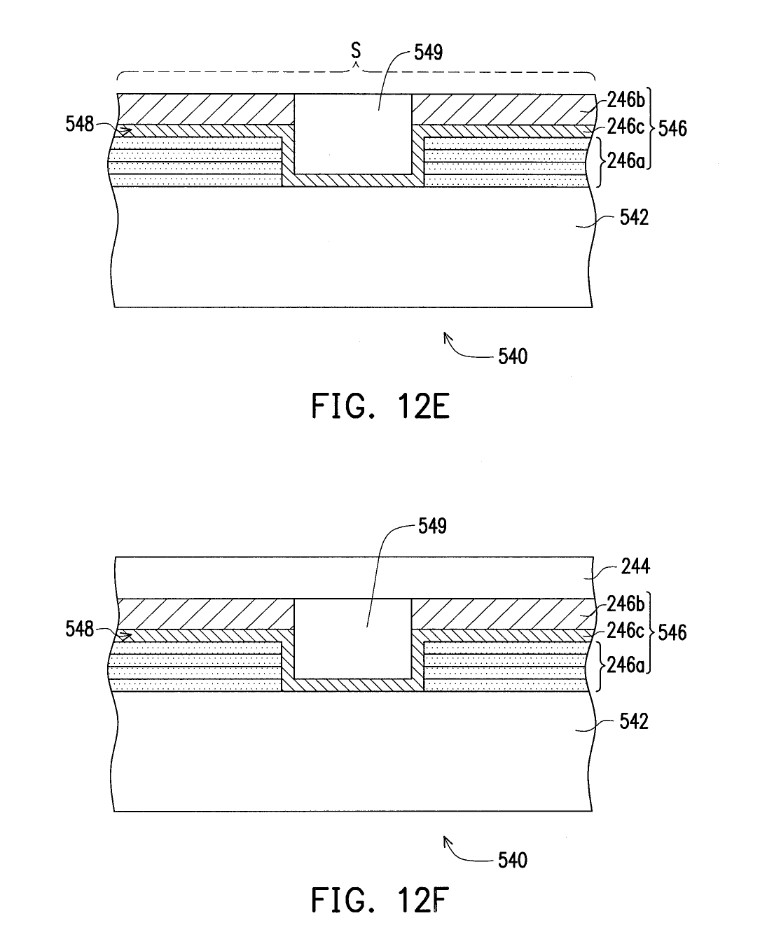

FIGS. 12A-12F are schematic diagrams illustrating a process of manufacturing the cover of FIG. 8. First, the substrate 542 shown in FIG. 12A is provided. Then, the color layer 546 is disposed on the substrate 542. In detail, referring to FIG. 12B, the white ink layer 246a is disposed on the substrate 542.

Then, referring to FIG. 12C, the icon region 548 is formed, where the white ink layer 246a is located between the icon region 548 and the substrate 542. Moreover, a color of the color layer 546 at the icon region 548 is different to a color of the other part of the color layer 546. For example, the color layer 546 has a gray ink layer 246c at the icon region 548 to highlight the icons of the icon region 548. Referring to FIG. 12D, the black ink layer 246b is disposed on the icon region 548. In the present embodiment, the icon region 548 of the color layer 546 has the depression 548a.

Moreover, referring to FIG. 12E, a filling material 549 fills in the depression 548a to commonly form the flat surface S with the color layer 546. Then, as shown in FIG. 12F, the adhesive layer 244 is configured to cover the color layer 546 and the substrate 242 (step S920).

In summary, by decreasing a height difference between the surface of the substrate and the surface of the color layer, generation of bubbles due to subsequent configuration of the adhesive layer can be effectively avoided, so as to enhance appearance aesthetics of the product.

It will be apparent to those skilled in the art that various modifications and variations can be made to the structure of the application without departing from the scope or spirit of the application. In view of the foregoing, it is intended that the application cover modifications and variations of this application provided they fall within the scope of the following claims and their equivalents.

What is claimed is:

1. A cover, comprising:
a substrate, having a thinning region;
an adhesive layer; and
a color layer, disposed in the thinning region and located between the substrate and the adhesive layer.

2. The cover as claimed in claim 1, wherein the substrate comprises a bottom plate and a filled layer, the bottom plate has a plane, the filled layer is disposed on the plane, a part of the plane that is not configured with the filled layer is the thinning region, and a surface of the filled layer is aligned with a surface of the color layer.

3. The cover as claimed in claim 2, wherein a material of the filled layer is UV glue, ink, optical clear adhesive or silicon dioxide.

4. The cover as claimed in claim 1, wherein the surface of the color layer is aligned with or higher than a surface of the substrate directly contacting the adhesive layer.

5. The cover as claimed in claim 1, further comprising a filling material, wherein the color layer has an icon region, the icon region has a depression, and the filling material fills in the depression to substantially form a flat surface with the color layer.

6. The cover as claimed in claim 5, wherein a color of the color layer at the icon region is different to a color of the other part of the color layer.

7. The cover as claimed in claim 1, wherein the color layer is an ink layer or a photoresist layer.

8. The cover as claimed in claim 7, wherein the color layer comprises a white ink layer and a black ink layer, and the black ink layer is located between the white ink layer and the adhesive layer.

9. An electronic device, comprising:
a body, comprising a display module; and
a cover, disposed on the display module, and the cover comprising:
a substrate, having a thinning region;
an adhesive layer; and
a color layer, disposed in the thinning region and located between the substrate and the adhesive layer.

10. The electronic device as claimed in claim 9, wherein the substrate comprises a bottom plate and a filled layer, the bottom plate has a plane, the filled layer is disposed on the plane, a part of the plane that is exposed by the filled layer is the thinning region, and a surface of the filled layer is aligned with a surface of the color layer.

11. The electronic device as claimed in claim 10, wherein a material of the filled layer is UV glue, ink, optical clear adhesive or silicon dioxide.

12. The electronic device as claimed in claim 9, wherein the surface of the color layer is aligned with or protrudes out from a surface of the substrate directly contacting the adhesive layer.

13. The electronic device as claimed in claim 9, further comprising a filling material, wherein the color layer has an icon region, the icon region has a depression, and the filling material fills in the depression to commonly form a flat surface with the color layer.

14. The electronic device as claimed in claim 13, wherein a color of the color layer at the icon region is different to a color of the other part of the color layer.

15. The electronic device as claimed in claim 9, wherein the color layer is an ink layer or a photoresist layer.

16. The electronic device as claimed in claim 15, wherein the color layer comprises a white ink layer and a black ink layer, and the black ink layer is located between the white ink layer and the adhesive layer.

17. A method for manufacturing a cover, comprising:
providing a substrate, wherein a color layer is disposed in a thinning region of the substrate; and
disposing an adhesive layer to cover the color layer and the substrate.

18. The method for manufacturing the cover as claimed in claim 17, wherein the step of providing the substrate comprises:
providing a bottom plate, wherein the bottom plate has a plane, and the color layer is disposed in the thinning region of the plane; and
disposing a filled layer on a part of the plane that is not configured with the color layer, and aligning a surface of the filled layer with a surface of the color layer.

19. The method for manufacturing the cover as claimed in claim 17, wherein the step of providing the substrate comprising:
forming the thinning region on the substrate; and
disposing the color layer in the thinning region of the substrate.

20. The method for manufacturing the cover as claimed in claim 17, wherein an icon region of the color layer has a depression, and the method for manufacturing the cover further comprises: filling a filling material in the depression to commonly form a flat surface with the color layer before the adhesive layer is configured.

21. The method for manufacturing the cover as claimed in claim 17, wherein a method for manufacturing the color layer comprises:
disposing a white ink layer in the thinning region of the substrate; and
disposing a black ink layer on the white ink layer.
